(19) United States
(12) Patent Application Publication
(10) Pub. No.: US 2023/0118912 A1
(43) Pub. Date: Apr. 20, 2023

(54) Techniques For Synchronous Accesses To Storage Circuits

(71) Applicant: Intel Corporation, Santa Clara, CA (US)

(72) Inventors: Jeffrey Schulz, Milpitas, CA (US); Terence Magee, San Francisco, CA (US)

(73) Assignee: Intel Corporation, Santa Clara, CA (US)

(21) Appl. No.: 18/084,158

(22) Filed: Dec. 19, 2022

(51) Int. Cl. G11C 7/22; G06F 3/06; G11C 7/10

(52) U.S. Cl. CPC G11C 7/222; G06F 3/0613; G06F 3/0629; G06F 3/0673; G11C 7/10; G11C 2207/2254

(57) ABSTRACT

A memory interface circuit includes first and second memory controller circuits that asynchronously receive requests for memory accesses to first and second storage circuits. The memory interface circuit also includes first and second clock gate circuits that disable and then reenable first and second clock signals in response to a clock enable signal. The first and the second memory controller circuits perform the memory accesses to the first and the second storage circuits synchronously in response to the first and the second clock signals that have been reenabled by the first and the second clock gate circuits.

### FIELD OF THE DISCLOSURE

The present disclosure relates to electronic circuits, and more particularly, to systems, circuits, and methods for synchronous accesses to storage circuits.

### BACKGROUND

Configurable logic integrated circuits can be configured by users to implement desired custom logic functions. In a typical scenario, a logic designer uses computer-aided design tools to design a custom circuit design. When the design process is complete, the computer-aided design tools generate configuration data. The configuration data is then loaded into configuration memory elements that configure configurable logic circuits in the integrated circuit to perform the functions of the custom circuit design. Configurable logic integrated circuits can be used for co-processing in big-data or fast-data applications. For example, configurable logic integrated circuits may be used in application acceleration tasks in a datacenter and may be reprogrammed during datacenter operation to perform different tasks.

### BRIEF DESCRIPTION OF THE DRAWINGS

FIG. 1 is a diagram that illustrates an example of a memory interface circuit that includes two memory controller circuits that can be operated in synchronization to enable high-speed memory accesses.

FIG. 2 is a flow chart that illustrates examples of operations that can be performed to access target storage circuits in the memory controller circuits in the memory interface circuit of FIG. 1 during synchronous operation.

FIG. 3 is a timing diagram that illustrates examples of waveforms for various signals generated by the memory interface circuit of FIG. 1.

FIG. 4 illustrates an example of a programmable integrated circuit (IC) that can be used to implement the memory interface circuit disclosed herein with respect to FIGS. 1-3.

### DETAILED DESCRIPTION

Many types of configurable logic integrated circuits have memory circuits and memory controller circuits that control accesses to the memory circuits. The memory controller circuits in a configurable logic integrated circuit are typically designed to be flexible and modular, so that the memory controller circuits can be used for many different custom circuit designs for the configurable logic integrated circuit. A configurable logic integrated circuit may, for example, have the flexibility to use an input/output circuit for a memory interface or for another application.

Enabling the usage of off-the-shelf or industry standard circuit designs from various sources is a significant challenge in designing architecture for configurable logic integrated circuits. A configurable logic integrated circuit can provide programmable width for memory controller circuits, so that the memory controller circuits can be used for a variety of different circuit designs. Multiple memory controller circuits in a configurable logic integrated circuit can be run together in lockstep operation to provide a single memory interface. Support for lockstep operation requires that the memory controller circuits in the memory interface remain in synchronization in order to process data presented to each memory controller circuit in the memory interface.

However, in some types of memory controller circuits, an access port to one or more registers is asynchronous, in order to provide the high-speed accesses required for some types of memory interface standards (e.g., Double Data Rate 5 (DDR5)). Writing to, or reading from, these registers can cause the memory controller circuits in the memory interface to go out of synchronization. Using synchronous register accesses, instead of asynchronous register accesses, slows the memory controller circuits down to undesirably slow speeds. Periodic calibration of the memory controller circuits may perform frequent register accesses to keep the memory interface functional. Using a different memory controller circuit for each configuration limits the flexibility and modularity of the memory interface. Restricting the configurations to slower memory access speeds, where the memory controller circuits do not need regular register access, is undesirable for high-speed memory interface standards.

According to some examples disclosed herein, multiple memory controller circuits in an integrated circuit (IC) are operated in synchronization to implement a single memory interface. The memory controller circuits can have asynchronous logic ports to storage circuits, such as registers. The memory interface circuit provides logic support for accesses to the storage circuits through the asynchronous logic ports. A handshake protocol can be used with the memory controller circuits to implement synchronous operation. The synchronous operation can be implemented using gating logic circuits that ensure that the asynchronous portion of each data transfer can settle out before restarting a synchronous clock signal. The synchronous operation enables a selectable number of the memory controller circuits with asynchronous logic ports to registers to be used in lockstep operation to implement the memory interface with high-speed memory accesses (e.g., using Double Data Rate 4 (DDR4), DDR5, or low power DDR5 standards). Thus, the memory interface provides flexibility and modularity in terms of the number of the memory controller circuits that can be used to implement the memory interface. Operating the memory controller circuits in synchronization can, for example, preserve the width flexibility of lockstep operation and the design modularity used for the development of configurable logic integrated circuits. The memory interface can be used with a variety of different memory interface standards and designs.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

This disclosure discusses integrated circuit devices, including configurable (programmable) logic devices such as field programmable gate arrays (FPGAs). As discussed herein, an integrated circuit (IC) may include hard logic and/or soft logic. As used herein, “hard logic” generally refers to circuits in an integrated circuit device that are not programmable by an end user. The circuits in an integrated circuit device (e.g., in a configurable IC) that are programmable by the end user are referred to as “soft logic.”

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices. The term “circuit” may mean one or more passive and/or active electrical components that are arranged to cooperate with one another to provide a desired function.

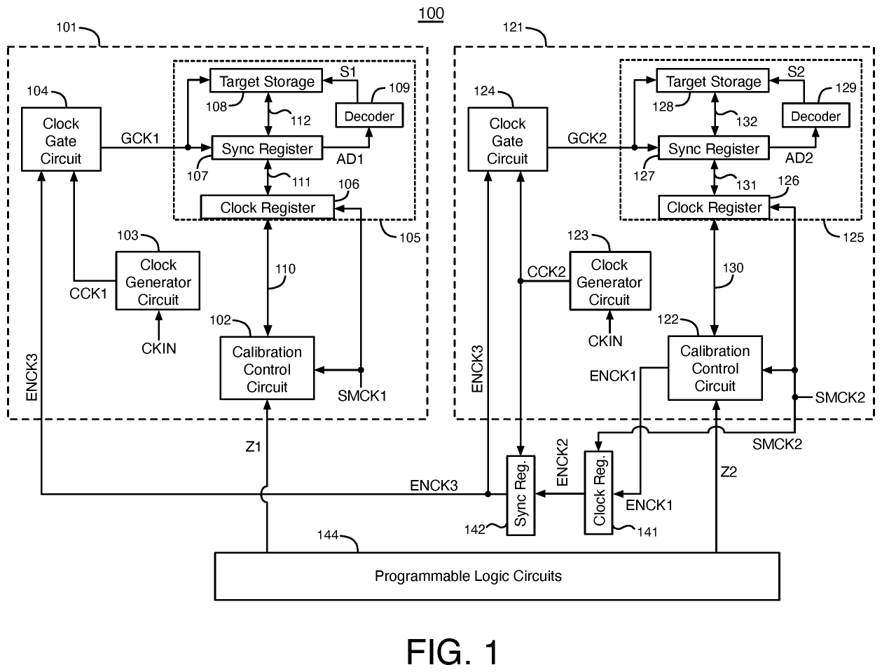

FIG. 1 is a diagram that illustrates an example of a memory interface circuit 100 that includes at least two memory controller circuits that can be operated in synchronization to enable high-speed memory accesses. In the example of FIG. 1, the memory interface circuit 100 includes a first input/output (IO) circuit 101, a second input/output (IO) circuit 121, a clock register 141, and a synchronization (sync) register 142. The IO circuit 101 includes a calibration control circuit 102, a clock generator circuit 103, a clock gate (or gating) circuit 104, a memory controller circuit 105, and a read/write bus 110. The memory controller circuit 105 includes a clock register 106, a synchronization (sync) register 107, target storage circuits 108, a decoder circuit 109, and busses 111-112. The IO circuit 121 includes a calibration control circuit 122, a clock generator circuit 123, a clock gate (or gating) circuit 124, a memory controller circuit 125, and a read/write bus 130. The memory controller circuit 125 includes a clock register 126, a synchronization (sync) register 127, target storage circuits 128, a decoder circuit 129, and busses 131-132.

Each of the registers disclosed herein is a storage circuit (also referred to as a memory circuit) that can be implemented, for example, by a sequential storage circuit such as a flip-flop circuit. The target storage circuits 108 and 128 can include sequential storage circuits (e.g., flip-flops) and/or non-sequential storage circuits (e.g., random access memory or RAM). The memory interface circuit 100 of FIG. 1 can be provided in any type of integrated circuit (IC) such as, for example, a configurable logic IC (e.g., a field programmable gate array (FPGA)), a microprocessor IC, a graphics processing unit IC, an application specific IC, a memory IC, etc. In the example shown in FIG. 1, the memory interface circuit 100 is coupled to programmable logic circuits 144 that are in a fabric region (i.e., core logic region) of a programmable/configurable logic IC. Only a portion of the programmable logic circuits in the fabric region of the IC are shown in FIG. 1. The programmable logic circuits 144 generate control signals Z1 and Z2 that are provided to calibration control circuits 102 and 122, respectively. Each of the IO circuits 101 and 121 can be coupled to external terminals (e.g., conductive pads) of the IC for transmitting and receiving signals between the memory interface 100 and external sources.

As shown in FIG. 1, a first clock signal SMCK1 is provided to an input of each of the calibration control circuit 102 and the clock register 106. A second clock signal SMCK2 is provided to an input of each of the calibration control circuit 122, the clock register 126, and the clock register 141. A third clock signal CKIN is provided to an input of each of the clock generator circuits 103 and 123. The clock signal CKIN provided to each of the clock generator circuits 103 and 123 is the same clock signal. Clock generator circuit 123 generates a controller clock signal CCK2 in response to the clock signal CKIN. Clock signal CCK2 is provided to an input of each of clock gate circuit 124 and sync register 142. Clock gate circuit 124 generates a clock signal GCK2 that is provided to an input of sync register 127 and to an input of target storage circuits 128. Clock generator circuit 103 generates another controller clock signal CCK1 in response to the clock signal CKIN. Clock signal CCK1 is provided to an input of clock gate circuit 104. Clock gate circuit 104 generates a clock signal GCK1 that is provided to an input of sync register 107 and to an input of target storage circuits 108. The clock generator circuits 103 and 123 can be, for example, phase-locked loops or delay-locked loops.

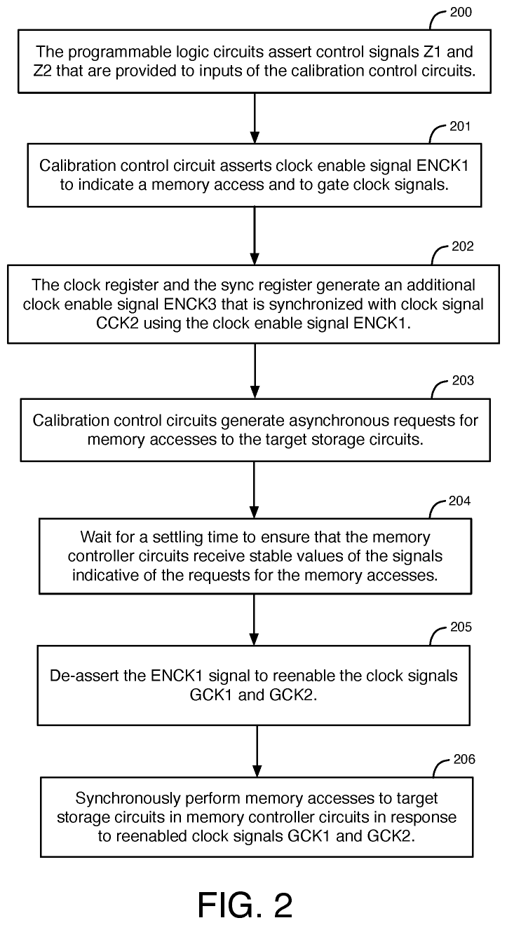

In the example of FIG. 1, the memory controller circuits 105 and 125 have asynchronous logic ports to access the target storage circuits 108 and 128, respectively. According to some examples disclosed herein, the memory controller circuits 105 and 125 can be operated in synchronization to enable high-speed memory accesses to the target storage circuits 108 and 128, as disclosed in further detail herein. FIG. 2 is a flow chart that illustrates examples of operations that can be performed to access the target storage circuits in the memory controller circuits 105 and 125 in the memory interface circuit 100 during synchronous operation.

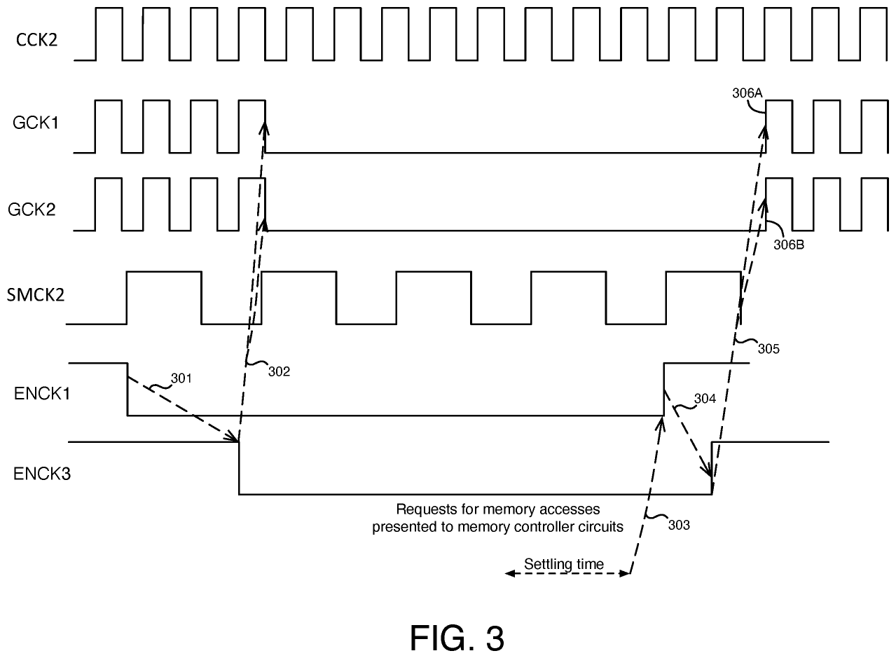

FIG. 3 is a timing diagram that illustrates examples of waveforms for various signals generated by the memory interface circuit 100 of FIG. 1. FIG. 3 illustrates examples of waveforms for the signals CCK2, GCK1, GCK2, ENCK1, and ENCK3 shown in FIG. 1. Initially, the clock gate circuit 104 generates the clock signal GCK1 by providing the rising and falling edges of clock signal CCK1 to clock signal GCK1, and the clock gate circuit 124 generates the clock signal GCK2 by providing the rising and falling edges of clock signal CCK2 to clock signal GCK2. As shown in FIG. 3, clock signals CCK2 and GCK2 initially have identical waveforms.

In operation 200 of FIG. 2, the programmable logic circuits 144 in the fabric region of the IC assert control signals Z1 and Z2 (shown in FIG. 1) that are provided to inputs of the calibration control circuits 102 and 122, respectively. In operation 201 of FIG. 2, the calibration control circuit 122 in the IO circuit 121 asserts a first clock enable signal ENCK1 to indicate a memory access and to gate clock signals GCK1 and GCK2 in response to control signal Z2 being asserted. The first clock enable signal ENCK1 is provided to an input of the clock register 141. In operation 202, clock register 141 and sync register 142 generate an additional clock enable signal ENCK3 that is synchronized with clock signal CCK2 using the clock enable signal ENCK1. Specifically, in operation 202, clock register 141 generates a second clock enable signal ENCK2 that is synchronized with the clock signal SMCK2 using the first clock enable signal ENCK1, and the sync register 142 generates a third clock enable signal ENCK3 that is synchronized with clock signal CCK2 using the second clock enable signal ENCK2. The registers 141-142 perform a clock crossing function for the clock enable signals ENCK1/ENCK2/ENCK3 from the clock domain of SMCK2 to the clock domain of CCK2. Registers 141-142 provide the rising and falling edges in clock enable signal ENCK1 to clock enable signal ENCK3.

The third clock enable signal ENCK3 is provided to an input of each of the clock gate circuits 104 and 124. In response to the calibration control circuit 122 asserting the clock enable signal ENCK1 in operation 201, registers 141-142 assert the clock enable signal ENCK3 in operation 202. In response to the clock enable signal ENCK3 being asserted, the clock gate circuits 104 and 124 gate off (i.e., disable) the clock signals GCK1 and GCK2, respectively. FIG. 3 illustrates examples of waveforms generated by these operations. As shown in FIG. 3, the calibration control circuit 122 can, for example, assert clock enable signal ENCK1 by generating a falling edge in clock enable signal ENCK1. Registers 141-142 propagate the falling edge in clock enable signal ENCK1 to clock enable signal ENCK3, as shown by arrow 301 in FIG. 3. Clock gate circuits 104 and 124 then gate off (i.e., disable) clock signals GCK1 and GCK2, respectively, in response to the falling edge in clock enable signal ENCK3, as shown, for example, by arrows 302 in FIG. 3. Clock signals GCK1 and GCK2 remain in logic low states, and do not have rising and falling edges, while these clock signals are gated off by the clock gate circuits 104 and 124, respectively, as shown in FIG. 3.

In operations 203, the calibration control circuits 102 and 122 generate asynchronous requests for memory accesses to the target storage circuits 108 and 128, respectively. The calibration control circuits 102 and 122 generate the asynchronous requests for the memory accesses to the target storage circuits in response to control signals Z1 and Z2 being asserted and in response to unsynchronized clock signals SMCK1 and SMCK2, respectively, and not in response to a single global clock signal or a single global clock source. Therefore, the calibration control circuits 102 and 122 are asynchronous circuits that generate the requests for the memory accesses to the target storage circuits asynchronously. In operations 203, the calibration control circuit 122 asynchronously generates signals on bus 130 that are indicative of a request for a read or write access to one of the target storage circuits 128, and the calibration control circuit 102 asynchronously generates signals on bus 110 that are indicative of a request for a read or write access to one of the target storage circuits 108. Calibration control circuits 102 and 122 can generate the signals indicative of the requests for the memory accesses on busses 110 and 130 concurrently, at different non-overlapping time periods, or in overlapping time periods.

Each request for a read access can include signals generated on bus 110 or 130 indicative of a read address and a read command. Each request for a write access can include signals generated on bus 110 or 130 indicative of write data, a write address, and a write command. The signals indicative of the requests for the memory accesses are asynchronously presented to the memory controller circuits 105 and 125 through busses 110 and 130, respectively, in operations 203. FIG. 3 illustrates approximate timing for the signals indicative of the requests being presented to the memory controller circuits on busses 110 and 130, while the clock signals GCK1 and GCK2 are gated off.

In operation 204, the calibration control circuit 122 waits for a settling time to ensure that the memory controller circuits 105 and 125 receive stable values of the signals indicative of the requests for the memory accesses on busses 110 and 130. FIG. 3 illustrates an example of the settling time of operation 204. During the settling time of operation 204, the signals indicative of the requests for the memory accesses on busses 110 and 130 are stored in the clock registers 106 and 126. Clock registers 106 and 126 synchronize the signals indicative of the requests for the memory accesses on busses 110 and 130 to clock signals SMCK1 and SMCK2, respectively.

In operation 205, the calibration control circuit 122 de-asserts the clock enable signal ENCK1 to reenable the gated clock signals GCK1 and GCK2. As shown in FIG. 3, the calibration control circuit 122 can, for example, de-assert clock enable signal ENCK1 by generating a rising edge in clock enable signal ENCK1 after the settling time, as shown by arrow 303. Registers 141-142 propagate the rising edge in clock enable signal ENCK1 to clock enable signal ENCK3, as shown by arrow 304 in FIG. 3. Clock gate circuits 104 and 124 then reenable clock signals GCK1 and GCK2, respectively, in response to the rising edge in clock enable signal ENCK3, as shown, for example, by arrows 305 in FIG. 3. Because clock signals GCK1 and GCK2 are reenabled by the same global clock enable signal ENCK3, the clock signals GCK1 and GCK2 are synchronized. Clock signals GCK1 and GCK2 then have rising and falling edges again after being reenabled, as shown in FIG. 3.

In operations 206, the memory controller circuits 105 and 125 synchronously perform the memory accesses to the target storage circuits 108 and 128 in response to the reenabled clock signals GCK1 and GCK2, respectively. The memory accesses performed in operations 206 are synchronous, because memory controller circuits 105 and 125 perform the memory accesses to storage circuits 108 and 128 in response to the synchronized clock signals GCK1 and GCK2. The memory controller circuits 105 and 125 store the signals indicative of the requests for the memory accesses in sync registers 107 and 127 at the same time in response to clock signals GCK1 and GCK2, respectively.

During operations 206, the signals indicative of the requests for the memory accesses are provided from the clock registers 106 and 126 through busses 111 and 131 to the sync registers 107 and 127, respectively. The sync registers 107 and 127 synchronize the signals indicative of the requests that are received from clock registers 106 and 126 to clock signals GCK1 and GCK2, for example, at rising edges 306A and 306B, respectively, shown in FIG. 3. The decoder circuits 109 and 129 decode the read or write addresses AD1 and AD2 from the signals indicative of the requests that are stored in registers 107 and 127 to generate select signals S1 and S2 for selecting the register or memory locations in target storage circuits 108 and 128 indicated by the read or write addresses AD1 and AD2, respectively.

During read accesses in operations 206, the target storage circuits 108 and 128 access read data from the register or memory locations indicated by the select signals S1 and S2 in response to the read commands from registers 107 and 127, respectively. The target storage circuits 108 and 128 then output the read data through busses 112 and 132 to the sync registers 107 and 127, respectively. The read data is then provided through busses 111 and 131, clock registers 106 and 126, and busses 110 and 130 to calibration control circuits 102 and 122, respectively.

During write accesses in operations 206, the sync registers 107 and 127 provide the write data and the write commands to the target storage circuits 108 and 128 through busses 112 and 132, respectively. The target storage circuits 108 and 128 then store the write data at the register or memory locations indicated by the select signals S1 and S2, respectively, in response to the write commands. In some instances, one of the memory controller circuits 105 or 125 can perform a write access to the target storage circuits, while the other memory controller circuit 105 or 125 performs a read access to the target storage circuits.

Although only 2 IO circuits 101 and 121 having 2 memory controller circuits are shown in FIG. 1 as an example, a memory interface circuit implementing techniques disclosed herein can have any number of IO circuits and memory controller circuits. The synchronous operation of the read and write accesses disclosed herein enables a selectable number of the memory controller circuits in the memory interface circuit to perform high-speed read and write accesses in lockstep operation. The memory interface circuit 100 provides flexibility and modularity in terms of the number of the memory controller circuits that can perform synchronous read and write accesses. Because the read and write accesses in the memory controller circuits are in synchronization, the memory interface circuit can have a selectable width for the read and write accesses. Each of the IO circuits 101 and 121 has a modular design that can be replicated for additional 10 circuits to provide a selectable width for the memory interface circuit having any number of memory controller circuits that can perform synchronous read and write accesses to the target storage circuits.

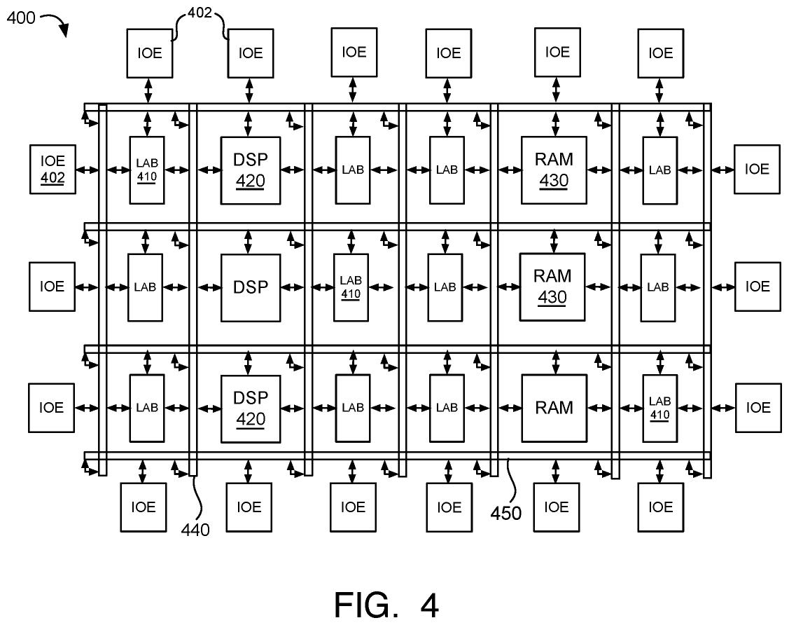

FIG. 4 illustrates an example of a programmable integrated circuit (IC) 400 that can be used to implement the memory interface circuit 100 disclosed herein with respect to FIGS. 1-3. As shown in FIG. 4, the programmable integrated circuit (IC) 400 includes a two-dimensional array of configurable functional circuit blocks, including configurable logic array blocks (LABs) 410 and other functional circuit blocks, such as random access memory (RAM) blocks 430 and digital signal processing (DSP) blocks 420. Functional blocks such as LABs 410 can include smaller programmable logic circuits (e.g., logic elements, logic blocks, or adaptive logic modules) that receive input signals and perform custom functions on the input signals to produce output signals.

In addition, programmable IC 400 can have input/output elements (IOEs) 402 for driving signals off of programmable IC 400 and for receiving signals from other devices. Input/output elements 402 may include parallel input/output circuitry, serial data transceiver circuitry, differential receiver and transmitter circuitry, or other circuitry used to connect one integrated circuit to another integrated circuit. As shown, input/output elements 402 may be located around the periphery of the chip. If desired, the programmable IC 400 may have input/output elements 402 arranged in different ways. For example, input/output elements 402 may form one or more columns, rows, or islands of input/output elements that may be located anywhere on the programmable IC 400.

The programmable IC 400 can also include programmable interconnect circuitry in the form of vertical routing channels 440 (i.e., interconnects formed along a vertical axis of programmable IC 400) and horizontal routing channels 450 (i.e., interconnects formed along a horizontal axis of programmable IC 400), each routing channel including at least one track to route at least one wire.

Note that other routing topologies, besides the topology of the interconnect circuitry depicted in FIG. 4, may be used. For example, the routing topology may include wires that travel diagonally or that travel horizontally and vertically along different parts of their extent as well as wires that are perpendicular to the device plane in the case of three dimensional integrated circuits. The driver of a wire may be located at a different point than one end of a wire.

Furthermore, it should be understood that embodiments disclosed herein with respect to FIGS. 1-3 may be implemented in any integrated circuit or electronic system. If desired, the functional blocks of such an integrated circuit may be arranged in more levels or layers in which multiple functional blocks are interconnected to form still larger blocks. Other device arrangements may use functional blocks that are not arranged in rows and columns.

Programmable IC 400 may contain programmable memory elements. Memory elements may be loaded with configuration data using input/output elements (IOEs) 402. Once loaded, the memory elements each provide a corresponding static control signal that controls the operation of an associated configurable functional block (e.g., LABs 410, DSP blocks 420, RAM blocks 430, or input/output elements 402).

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The programmable memory elements may be organized in a configuration memory array consisting of rows and columns. A data register that spans across all columns and an address register that spans across all rows may receive configuration data. The configuration data may be shifted onto the data register. When the appropriate address register is asserted, the data register writes the configuration data to the configuration memory bits of the row that was designated by the address register.

In certain embodiments, programmable IC 400 may include configuration memory that is organized in sectors, whereby a sector may include the configuration RAM bits that specify the functions and/or interconnections of the subcomponents and wires in or crossing that sector. Each sector may include separate data and address registers.

The programmable IC of FIG. 4 is merely one example of an IC that can include embodiments disclosed herein. The embodiments disclosed herein may be incorporated into any suitable integrated circuit or system. For example, the embodiments disclosed herein may be incorporated into numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein may be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein may be stored in non-transitory computer readable storage media. Non-transitory computer readable storage media is tangible computer readable storage media that stores data for access at a later time, as opposed to media that only transmits propagating electrical signals (e.g., wires). The software code may sometimes be referred to as software, data, program instructions, instructions, or code. The non-transitory computer readable storage media may, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

Additional examples are now described. Example 1 is a memory interface circuit comprising: first and second memory controller circuits that asynchronously receive requests for memory accesses to first and second storage circuits; and first and second clock gate circuits that disable and then reenable first and second clock signals in response to a clock enable signal, wherein the first and the second memory controller circuits perform the memory accesses to the first and the second storage circuits synchronously in response to the first and the second clock signals that have been reenabled by the first and the second clock gate circuits.

In Example 2, the memory interface circuit of Example 1 further comprises: a first control circuit that generates the clock enable signal and that asynchronously generates a first one of the requests for accessing the first storage circuit.

In Example 3, the memory interface circuit of Example 2 further comprises: a second control circuit that asynchronously generates a second one of the requests for accessing the second storage circuit.

In Example 4, the memory interface circuit of any one of Examples 1-3 can optionally include, wherein the first memory controller circuit asynchronously receives a first one of the requests for a first one of the memory accesses to the first storage circuit, and wherein the second memory controller circuit asynchronously receives a second one of the requests for a second one of the memory accesses to the second storage circuit.

In Example 5, the memory interface circuit of any one of Examples 1-4 can optionally include, wherein the first memory controller circuit performs a first one of the memory accesses to the first storage circuit in response to a first one of the requests; and wherein the second memory controller circuit performs a second one of the memory accesses to the second storage circuit in response to a second one of the requests.

In Example 6, the memory interface circuit of any one of Examples 1-5 can optionally include, wherein the first memory controller circuit comprises a first register that stores a first one of the requests in response to a third clock signal and a second register that receives the first one of the requests from the first register and stores the first one of the requests in response to the first clock signal.

In Example 7, the memory interface circuit of Example 6 can optionally include, wherein the second memory controller circuit comprises a third register that stores a second one of the requests in response to a fourth clock signal and a fourth register that receives the second one of the requests from the third register and stores the second one of the requests in response to the second clock signal.

In Example 8, the memory interface circuit of any one of Examples 1-5 further comprises: a first clock generator circuit that generates a third clock signal, wherein the first clock gate circuit generates the first clock signal based on the third clock signal; and a second clock generator circuit that generates a fourth clock signal, wherein the second clock gate circuit generates the second clock signal based on the fourth clock signal.

In Example 9, the memory interface circuit of any one of Examples 1-8 further comprises: a first calibration control circuit that asserts the clock enable signal to disable the first and the second clock gate circuits in response to a first control signal generated by programmable logic circuits in a fabric region of an integrated circuit; and a second calibration control circuit that asynchronously generates one of the requests for accessing the second storage circuit in response to a second control signal generated by the programmable logic circuits.

Example 10 is an integrated circuit comprising: a first memory controller circuit that asynchronously receives a first request for a first memory access to a first storage circuit; a first clock gate circuit that generates a first clock signal; a second memory controller circuit that asynchronously receives a second request for a second memory access to a second storage circuit; a second clock gate circuit that generates a second clock signal; and a control circuit that causes the first and the second clock gate circuits to disable and then reenable the first and the second clock signals to generate reenabled first and second clock signals, wherein the first and the second memory controller circuits perform the first and the second memory accesses to the first and the second storage circuits synchronously in response to the reenabled first and second clock signals.

In Example 11, the integrated circuit of Example 10 can optionally include, wherein the control circuit generates a clock enable signal that causes the first and the second clock gate circuits to disable and then reenable the first and the second clock signals to generate the reenabled first and second clock signals.

In Example 12, the integrated circuit of any one of Examples 10-11 can optionally include, wherein the first memory access comprises a first read access to the first storage circuit, and wherein the control circuit provides a read command and read data asynchronously to the first memory controller circuit to perform the first read access.

In Example 13, the integrated circuit of any one of Examples 10-12 can optionally include, wherein the first memory access comprises a first write access to the first storage circuit, and wherein the control circuit provides a write command, a write address, and write data asynchronously to the first memory controller circuit for the first write access.

In Example 14, the integrated circuit of any one of Examples 10-13 further comprises: an additional control circuit that provides a read command and read data asynchronously to the second memory controller circuit to perform the second memory access, wherein the second memory access comprises a second read access.

In Example 15, the integrated circuit of any one of Examples 10-13 further comprises: an additional control circuit that provides a write command, write data, and a write address asynchronously to the second memory controller circuit to perform the second memory access, wherein the second memory access comprises a write access.

Example 16 is a method for performing synchronous accesses to first and second memory circuits, the method comprises: receiving a first asynchronous request for a first access to the first memory circuit at a first memory controller circuit; receiving a second asynchronous request for a second access to the second memory circuit at a second memory controller circuit; gating off first and second clock signals generated by first and second clock gate circuits; causing the first and the second clock gate circuits to reenable the first and the second clock signals; and performing the first and the second accesses synchronously using the first and the second memory controller circuits in response to the first and the second clock signals after being reenabled by the first and the second clock gate circuits.

In Example 17, the method of Example 16 can optionally include, wherein gating off the first and the second clock signals comprises asserting a first clock enable signal using a control circuit to cause the first and the second clock gate circuits to gate off the first and the second clock signals.

In Example 18, the method of Example 17 can optionally include, wherein gating off the first and the second clock signals further comprises generating a second clock enable signal based on the first clock enable signal using a register and synchronizing the second clock enable signal with a third clock signal that is used by the first clock gate circuit to generate the first clock signal.

In Example 19, the method of any one of Examples 17-18 can optionally include, wherein causing the first and the second clock gate circuits to reenable the first and the second clock signals comprises de-asserting the first clock enable signal using the control circuit to cause the first and the second clock gate circuits to reenable the first and the second clock signals.

In Example 20, the method of any one of Examples 16-19 can optionally include, wherein performing the first and the second accesses synchronously using the first and the second memory controller circuits further comprises: performing the first access to the first memory circuit in response to the first asynchronous request using the first memory controller circuit; and performing the second access to the second memory circuit in response to the second asynchronous request using the second memory controller circuit.

In Example 21, the method of any one of Examples 16-20 further comprises: generating the first asynchronous request at a first control circuit; and generating the second asynchronous request at a second control circuit.

The foregoing description of the examples has been presented for the purpose of illustration. The foregoing description is not intended to be exhaustive or to be limiting to the examples disclosed herein. In some instances, features of the examples can be employed without a corresponding use of other features as set forth. Many modifications, substitutions, and variations are possible in light of the above teachings.

What is claimed is:

1. A memory interface circuit comprising:
first and second memory controller circuits that asynchronously receive requests for memory accesses to first and second storage circuits; and
first and second clock gate circuits that disable and then reenable first and second clock signals in response to a clock enable signal, wherein the first and the second memory controller circuits perform the memory accesses to the first and the second storage circuits synchronously in response to the first and the second clock signals that have been reenabled by the first and the second clock gate circuits.

2. The memory interface circuit of claim 1 further comprising:
a first control circuit that generates the clock enable signal and that asynchronously generates a first one of the requests for accessing the first storage circuit.

3. The memory interface circuit of claim 2 further comprising:
a second control circuit that asynchronously generates a second one of the requests for accessing the second storage circuit.

4. The memory interface circuit of claim 1, wherein the first memory controller circuit asynchronously receives a first one of the requests for a first one of the memory accesses to the first storage circuit, and wherein the second memory controller circuit asynchronously receives a second one of the requests for a second one of the memory accesses to the second storage circuit.

5. The memory interface circuit of claim 1, wherein the first memory controller circuit performs a first one of the memory accesses to the first storage circuit in response to a first one of the requests; and
wherein the second memory controller circuit performs a second one of the memory accesses to the second storage circuit in response to a second one of the requests.

6. The memory interface circuit of claim 1, wherein the first memory controller circuit comprises a first register that stores a first one of the requests in response to a third clock signal and a second register that receives the first one of the requests from the first register and stores the first one of the requests in response to the first clock signal.

7. The memory interface circuit of claim 6, wherein the second memory controller circuit comprises a third register that stores a second one of the requests in response to a fourth clock signal and a fourth register that receives the second one of the requests from the third register and stores the second one of the requests in response to the second clock signal.

8. The memory interface circuit of claim 1 further comprising:
a first clock generator circuit that generates a third clock signal, wherein the first clock gate circuit generates the first clock signal based on the third clock signal; and
a second clock generator circuit that generates a fourth clock signal, wherein the second clock gate circuit generates the second clock signal based on the fourth clock signal.

9. The memory interface circuit of claim 1 further comprising:
a first calibration control circuit that asserts the clock enable signal to disable the first and the second clock gate circuits in response to a first control signal generated by programmable logic circuits in a fabric region of an integrated circuit; and
a second calibration control circuit that asynchronously generates one of the requests for accessing the second storage circuit in response to a second control signal generated by the programmable logic circuits.

10. An integrated circuit comprising:
a first memory controller circuit that asynchronously receives a first request for a first memory access to a first storage circuit;
a first clock gate circuit that generates a first clock signal;
a second memory controller circuit that asynchronously receives a second request for a second memory access to a second storage circuit;
a second clock gate circuit that generates a second clock signal; and
a control circuit that causes the first and the second clock gate circuits to disable and then reenable the first and the second clock signals to generate reenabled first and second clock signals, wherein the first and the second memory controller circuits perform the first and the second memory accesses to the first and the second storage circuits synchronously in response to the reenabled first and second clock signals.

11. The integrated circuit of claim 10, wherein the control circuit generates a clock enable signal that causes the first and the second clock gate circuits to disable and then reenable the first and the second clock signals to generate the reenabled first and second clock signals.

12. The integrated circuit of claim 10, wherein the first memory access comprises a first read access to the first storage circuit, and wherein the control circuit provides a read command and read data asynchronously to the first memory controller circuit to perform the first read access.

13. The integrated circuit of claim 10, wherein the first memory access comprises a first write access to the first storage circuit, and wherein the control circuit provides a write command, a write address, and write data asynchronously to the first memory controller circuit for the first write access.

14. The integrated circuit of claim 10 further comprising:
an additional control circuit that provides a read command and read data asynchronously to the second memory controller circuit to perform the second memory access, wherein the second memory access comprises a second read access.

15. The integrated circuit of claim 10 further comprising:
an additional control circuit that provides a write command, write data, and a write address asynchronously to the second memory controller circuit to perform the second memory access, wherein the second memory access comprises a write access.

16. A method for performing synchronous accesses to first and second memory circuits, the method comprises:
receiving a first asynchronous request for a first access to the first memory circuit at a first memory controller circuit;
receiving a second asynchronous request for a second access to the second memory circuit at a second memory controller circuit;
gating off first and second clock signals generated by first and second clock gate circuits;
causing the first and the second clock gate circuits to reenable the first and the second clock signals; and
performing the first and the second accesses synchronously using the first and the second memory controller circuits in response to the first and the second clock signals after being reenabled by the first and the second clock gate circuits.

17. The method of claim 16, wherein gating off the first and the second clock signals comprises asserting a first clock enable signal using a control circuit to cause the first and the second clock gate circuits to gate off the first and the second clock signals.

18. The method of claim 17, wherein gating off the first and the second clock signals further comprises generating a second clock enable signal based on the first clock enable signal using a register and synchronizing the second clock enable signal with a third clock signal that is used by the first clock gate circuit to generate the first clock signal.

19. The method of claim 17, wherein causing the first and the second clock gate circuits to reenable the first and the second clock signals comprises de-asserting the first clock enable signal using the control circuit to cause the first and the second clock gate circuits to reenable the first and the second clock signals.

20. The method of claim 16, wherein performing the first and the second accesses synchronously using the first and the second memory controller circuits further comprises:
performing the first access to the first memory circuit in response to the first asynchronous request using the first memory controller circuit; and
performing the second access to the second memory circuit in response to the second asynchronous request using the second memory controller circuit.

21. The method of claim 16 further comprising:
generating the first asynchronous request at a first control circuit; and
generating the second asynchronous request at a second control circuit.
